(19) United States
(12) Patent Application Publication
(10) Pub. No.: US 2024/0388263 A1
(43) Pub. Date: Nov. 21, 2024

(54) WIDEBAND SWITCHING GAIN ENHANCED TUNABLE LNA ARCHITECTURE

(71) Applicant: pSemi Corporation, San Diego, CA (US)

(72) Inventors: Emre AYRANCI, Costa Mesa, CA (US); Jubaid QAYYUM, San Diego, CA (US); Miles Sanner, San Diego, CA (US)

(21) Appl. No.: 18/452,467

(22) Filed: Aug. 18, 2023

Related U.S. Application Data
(60) Provisional application No. 63/502,263, filed on May 15, 2023.

(51) Int. Cl. H03F 3/193; H03F 1/26

(52) U.S. Cl. CPC H03F 3/193; H03F 1/26; H03F 2200/294; H03F 2200/451

(57) ABSTRACT

Low noise amplifier (LNA) architectures addressing the parasitic challenges in the circuit in order to meet the high gain and bandwidth requirement at higher frequencies are disclosed. The described LNAs include cascode transistors and implement a tunable inductor in series with the gate terminal of a transistor of the cascode transistors to improve the gain and bandwidth of the LNAs and achieve high gain wideband switching LNAs.

### CROSS REFERENCE TO RELATED APPLICATIONS

The present application claims priority to U.S. Provisional Application No. 63/502,263 filed on May 15, 2023, and incorporated herein by reference in its entirety.

### TECHNICAL FIELD

The present disclosure is related to low noise amplifiers (LNAs). More in particular, the disclosed methods and devices address the problem of enhanced gain and tunability in wider band high frequency applications.

### BACKGROUND

The telecommunications industry is witnessing a trend towards the utilization of higher frequencies in various applications. However, this shift presents a significant challenge in meeting the gain and bandwidth requirements using conventional LNA techniques. This is primarily due to the manifestation of device parasitics, which limits the performance of LNAs, especially at higher frequencies. These parasitic elements are inherent to the devices and cannot be eliminated entirely.

Improved LNA architectures that can overcome such limitations and meet the gain and bandwidth requirements for wideband applications are therefore needed.

### SUMMARY

The described methods and circuits address the above-mentioned problem by reducing the effect of the device parasitics on the overall LNA performance while enabling wideband switching of tunable high frequency LNAs.

Throughout the rest of this document, an exemplary LNA architecture such as the one shown in FIG. 1 will be used to describe more in detail the problem addressed and the corresponding disclosed solutions. As it will become apparent later in the document, the described solutions can be applied to LNA architectures other than the one shown in FIG. 1.

LNA (100) of FIG. 1 comprises cascode transistors (M1, M2), inductors (L1, L2) coupled to the drain terminal of transistor (M2), input matching circuit (101) including series inductor (Lser) and shunt inductor (Lsh), the circuit coupling input terminal (IN) to the gate terminal of transistor (M1). LNA (100) further includes degenerative inductor (Ldeg) connected to the source terminal of transistor (M1). Degenerative inductor (Ldeg may be used to improve linearity in low gain modes. For example, a smaller value for the degenerative inductor may be used in a high gain mode, and a larger value for the degeneration inductor Ldeg may be used in a low gain mode. or modes. Also shown variable capacitors (C1, C2, Cbypass, Cblock), resistors (R1, Rfb). Transistors (M1, M2) are arranged a common-source and common-gate configurations, respectively. LNA (100) is configured to receive an input signal at input terminal (IN) and to generate an amplified signal at output terminal (OUT), across load resistor (RL).

LNA (100) of FIG. 1 further comprises a switching network including switches (SW1, SW2, SW3). The state of each switch can be selectively controlled base on the application. For example, LNA (100A) can be configured to operate in a low gain or high gain mode depending on the states of switches (SW1, SW2, SW3).

With further reference to FIG. 1, the switches (SW1, SW2, SW3) can selectively switch in and out various elements of the circuit to adapt to different applications. As an example, when switches (SW1, SW2) are open, both inductors (L1, L2) are switched in. On the other hand, when switch (SW2) is closed, inductor (L2) is switched out. The series combination of (L1, L2) may be used to cater for wider band applications. In the case of the narrow band applications and depending on the design requirements, inductor (L2) may be switched out. A combination of (L1 and/or L2) with capacitors (C1, C2) and resistor (R1) performs the output matching functionality. Resistor (Rfb) is essentially a feedback resistor implemented to increase the operational bandwidth. Capacitor (Cblock) is a direct current (DC) blocking capacitor.

With reference to FIG. 1, at higher frequencies, device parasitics play a dominant role in determining the performance of LNA (100). The gain of the LNA (100) experiences rapid roll-off at higher frequencies, thereby adversely affecting the overall gain performance for wider bandwidths. This decline in gain performance, in turn, impacts the band tunability of the LNA, particularly at higher frequencies.

As will be detailed in the rest of the document, the disclosed circuits and methods address the above-mentioned gain roll-off issue by mitigating the impact of parasitics. As a result, the overall performance of the LNA at higher frequencies can be improved.

According to a first aspect of the present disclosure, a low noise amplifier (LNA) is provided, comprising a first transistor and a second transistor arranged in a series configuration, and a tunable inductor coupling a gate terminal of the second transistor to ground; wherein the LNA is configured to receive an input signal at an input terminal coupled to the first transistor, and to generate an amplified signal at an output terminal coupled to the second transistor; and the tunable inductor is configured such that a gate-source voltage of the second transistor generated in presence of the tunable inductor is larger than a gate-source voltage of the second transistor generated in absence of the tunable inductor.

According to a second aspect of the present disclosure, a low noise amplifier (LNA) is provided, comprising a first transistor and a second transistor, and a first tunable inductor coupling a drain terminal of the first transistor to a source-terminal of the second transistor; wherein the LNA is configured to receive an input signal at an input terminal coupled to the first transistor, and to generate an amplified signal at an output terminal coupled to the second transistor; and the first tunable inductor is configured such that a gate-source voltage of the second transistor generated in presence of the first tunable inductor is larger than a gate-source voltage of the second transistor generated in absence of the first tunable inductor.

According to a third aspect of the present disclosure, a low noise amplifier (LNA) is provided, comprising a first transistor and two or more additional transistors, the first transistor and the two or more additional transistors being arranged in a series configuration, and one or more tunable inductors coupling gate terminals of corresponding additional transistors of the two or more additional transistors to ground; wherein the LNA is configured to receive an input signal at an input terminal coupled to the first transistor, and to generate an amplified signal at an output terminal coupled to an additional transistor; of the two or more additional transistors; and the one or more tunable inductors are configured such that gate-source voltages of corresponding additional transistors of the two or more additional transistors generated in presence of the one or more tunable inductors are larger than gate-source voltages of said corresponding additional transistors of the two or more additional transistors generated in absence of the one or more tunable inductors.

According to a fourth aspect of the present disclosure, a method of improving a gain roll off at higher frequency in a low noise amplifier (LNA) is disclosed, the LNA including a first transistor and second transistor arranged in a series configuration, the method comprising applying an input signal to a gate terminal of the first transistor to generate an amplified signal at a drain terminal of the second transistor; using a tunable inductor to couple a gate terminal of the second transistor to ground; and tuning the tuning inductor such that a gate-source voltage of the second transistor is larger than a gate-source voltage of the second transistor in absence of the tunable inductor.

According to a fifth aspect of the present disclosure, a method of improving a gain roll off at higher frequencies in transistor implemented in a common-gate configuration, comprising applying an input signal to a source-terminal of the transistor to generate an amplified signal at a drain terminal of the transistor; using a tunable inductor to couple a gate terminal of the transistor to ground; and tuning the tuning inductor such that a gate-source voltage of the transistor is larger than the gate-source voltage of the transistor in the absence of the tunable inductor.

Further aspects of the disclosure are provided in the description, drawings and claims of the present application.

### DESCRIPTION OF THE DRAWINGS

FIG. 1 shows an LNA.

FIG. 2A shows an exemplary LNA in accordance with embodiments of the present disclosure.

FIG. 2B shows an exemplary table illustrating the switching states of the switches in the embodiment of FIG. 2A.

FIG. 3A shows a transistor implemented in common-gate configuration on the left and the same transistor implementing a series inductor at the gate terminal on the right

FIG. 3B shows the variation of the gate-source voltage of the transistor corresponding to the configurations shown in FIG. 3A

FIG. 4 shows a small-signal equivalent of a transistor arranged in a common-gate configuration, the transistor implementing an inductor at the gate terminal

FIGS. 5A-5E and 6 show graphs illustrating a performance comparison for the embodiments shown in FIGS. 1 and 2.

FIGS. 7-9 show exemplary LNAs in accordance with embodiments of the present disclosure.

FIG. 10 shows a transistor arranged in a common-gate configuration and implementing the teachings of the present disclosure. Like reference numbers and designations in the various drawings indicate like elements.

### DETAILED DESCRIPTION

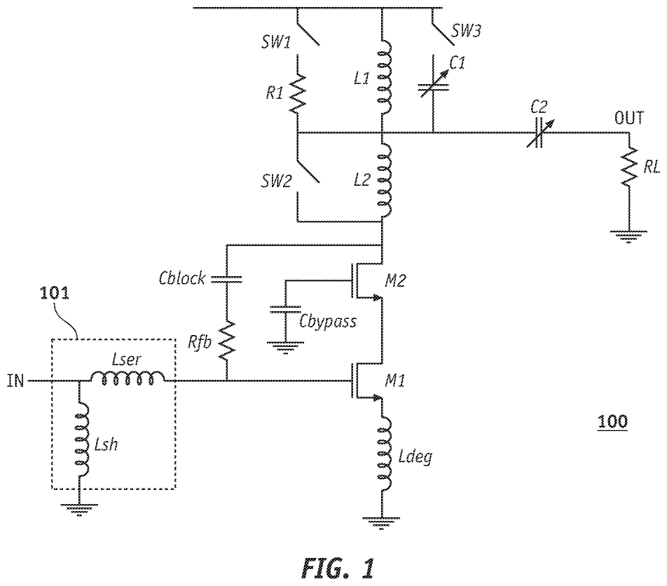

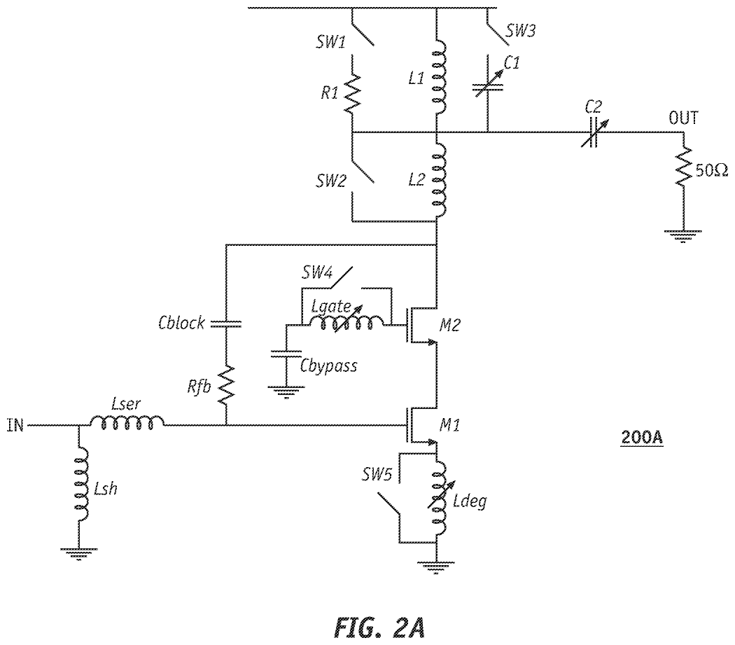

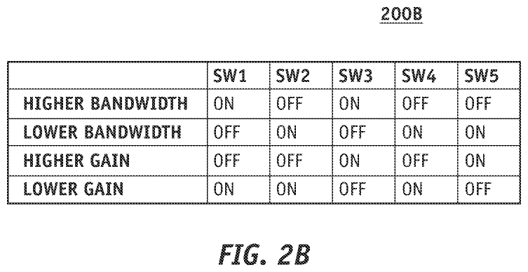

FIG. 2A shows an exemplary LNA (200A) according to an embodiment of the present disclosure. The structure and functionality of LNA (200A) is similar to what was described previously with regards to LNA (100) of FIG. 1. The main difference is the addition of tunable inductor (Lgate) connected to the gate terminal of transistor (M2). The tunable inductor may also be selectively switchable via switch (SW4). The inclusion of tunable inductor (Lgate) results in a larger voltage-drop across the capacitance (Cgs) of transistor (M2) when compared to cases where the tunable inductor is absent. This will result in an improvement of the effective transconductance and gain of the cascode stage including transistors (M1, M2). According to the teachings of the present disclosure, degenerative inductor (Ldeg) may be implemented as tunable and also may be selectively switchable via switch (SW5). FIG. 2B shows an exemplary table (200B) illustrating various gain-bandwidth combinations based on the states of switches (SW1, . . . , SW5). This table is not intended to be comprehensive, but rather provides a condensed overview that qualitatively demonstrates the impact of switch states on the variations (whether increasing or decreasing) in the bandwidth and gain of the LNA (200A) of FIG. 2A.

With continued reference to FIG. 2A, although tunable inductor (Lgate) increases the noise voltage of transistor (M2) which has a common-gate configuration, such tunable inductor may resonate out the parasitic capacitance at the source-terminal of transistor (M2), and as a result, the overall minimum noise figure (NF) is not deteriorated.

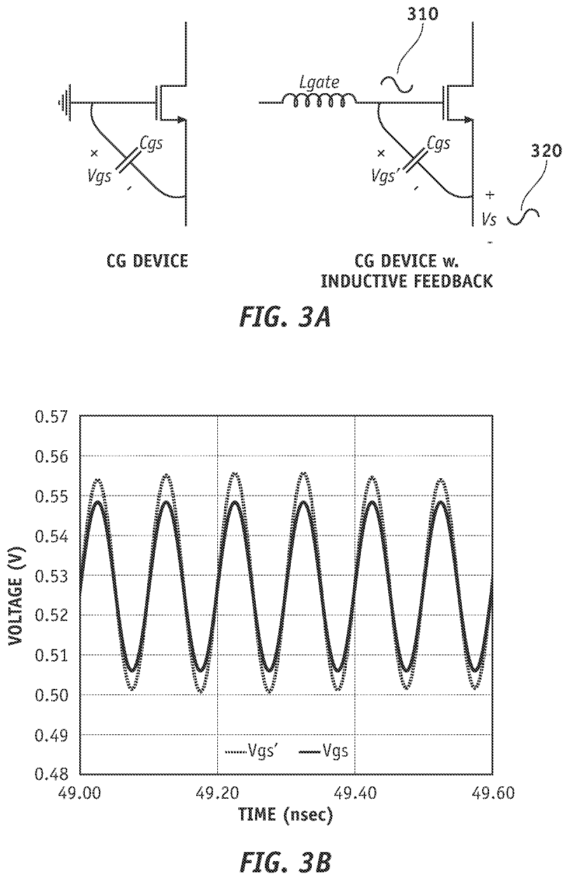

With further reference to FIG. 2A, as mentioned above, the addition of tunable inductor (Lgate) has the benefit of providing a larger voltage drop across capacitance (Cgs) of transistor (M2) when compared to cases where the tunable inductor is absent. According to the teachings of the present disclosure, it can be determined, using small-signal analysis, that when implementing tunable inductor (Lgate), an out-of-phase voltage can be generated at the gate terminal of transistor (M2) if the operating frequency f₀ is less than the resonant frequency fᵣ=1/2π√L_{gate}C_{gs}. This is illustrated in FIG. 3A, wherein the diagrams on the left-hand and right-hand side show transistor (M2) of FIG. 2 with and without tunable inductor (Lgate), respectively. Voltage (310) represents the voltage (Vgs') across capacitance (Cgs) of transistor (M2) and voltage (320) represents the voltage (Vs) at the source-terminal of transistor (M2). As can be noticed, such voltages are out of phase and satisfy the following equation:

$${Vgs}^{′} = \frac{1}{1 - {( 2 π {f}_{0} )}^{2} {L}_{g a t e} {C}_{g s}} Vs = \frac{1}{1 - {( {f}_{0} / {f}_{r} )}^{2}} Vs$$

From the above equation, it is evident that for f₀<fᵣ, Vgs' has a larger swing than Vgs. This is also illustrated in FIG. 3B where it can be noticed that the amplitude of voltage (Vgs'), i.e. when tunable inductor (Lgate) is implemented, is larger than that of voltage (Vgs), i.e. the tunable inductor is not implemented.

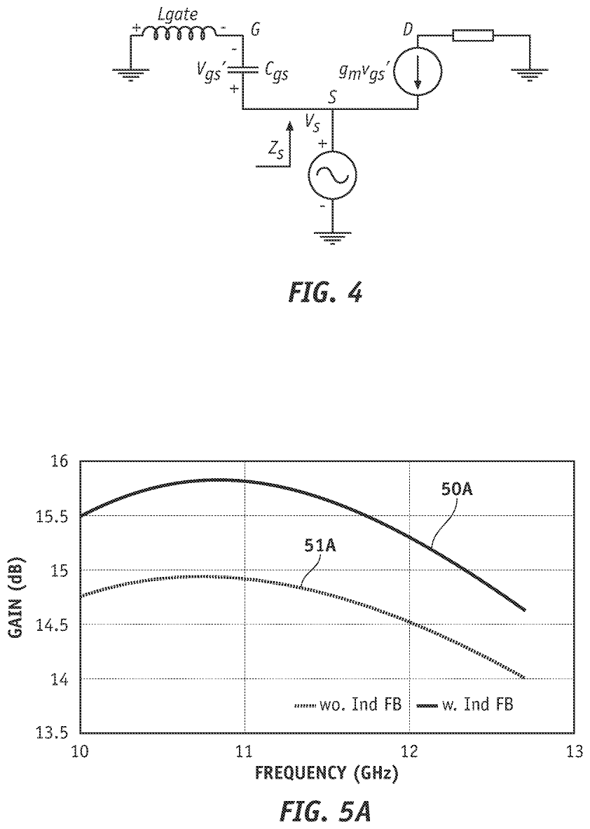

With reference to FIG. 2A, continuing with the small signal analysis, reference is made to FIG. 4 showing the small-signal equivalent diagram for transistor (M2) with the tunable inductor (Lgate) implemented. The impedance Z_{S} looking into the source-terminal of transistor (M2) can be calculated as follows:

$$\frac{1}{{Z}_{S}} = \frac{1}{( j w {L}_{g a t e} + 1 / {jwC}_{g s} )} + \frac{{g}_{m}}{( 1 - {( 2 π {f}_{0} )}^{2} {L}_{g a t e} {C}_{g s} )} ⇒ {Z}_{s} = \frac{( 1 - {( 2 π {f}_{0} )}^{2} {L}_{g a t e} {C}_{g s} )}{j w {C}_{g s} + {g}_{m}}$$

An increase in L_{gate} would reduce Z_{S} as long as L_{gate} is small enough such that fᵣ=1/2π√L_{gate}C_{gs}>f₀, keeping the numerator positive), and as a result, more RF current would flow from the drain terminal of transistor (M1) to the source-terminal of transistor (M2) of FIG. 2A, boosting the transconductance of the cascode.

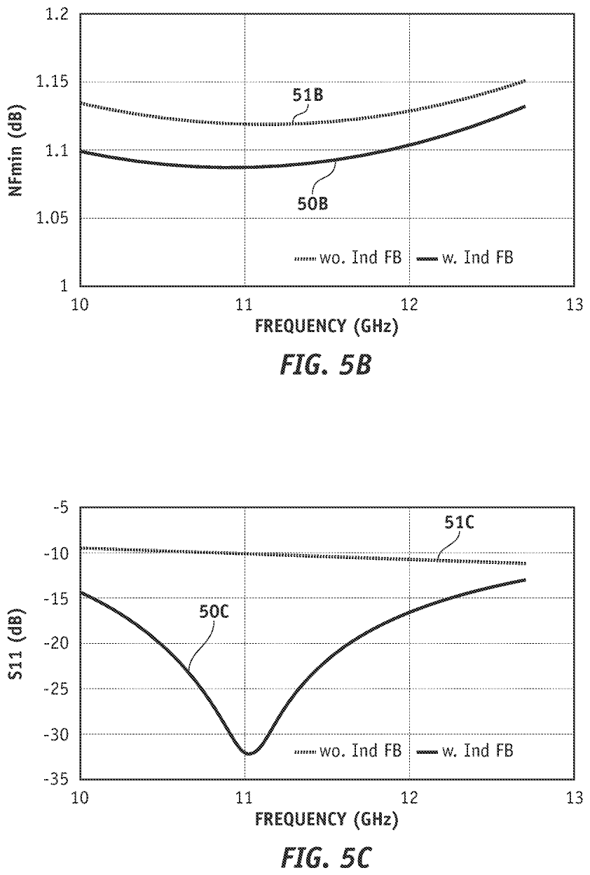

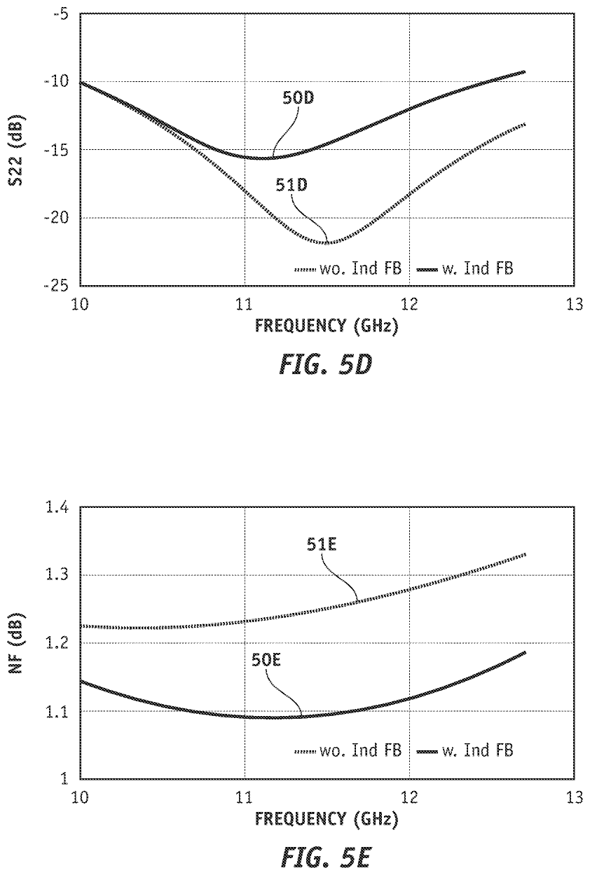

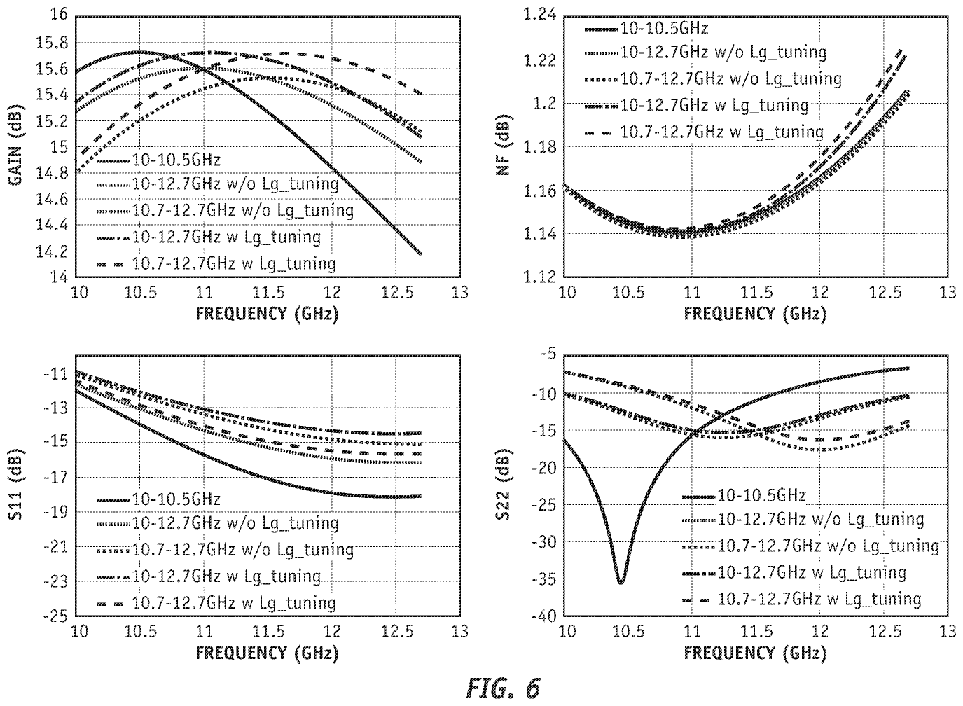

The graphs shown in FIGS. 5A-5E represent a comparison of the performances of LNAs (100, 200A) of FIGS. 1-2A indicating the impact of the addition of tunable inductor (Lgate). Curves (50A-50E) represent the performance of LNA (200A) of FIG. 2A while curves (51A-51E) correspond to that of LNA (100) of FIG. 1. Performances are expressed in terms of Gain, S11, NF, NFmin, and S22. Here are a few observations:
The overall gain is substantially improved by adding the tunable inductor (denoted as “w. Ind FB”) while some improvements in terms of the minimum NF can also be achieved.
S11 is improved due to the addition of the tunable inductor
NF improvement is mainly because of the S11 improvement that have resulted from the change in the impedance looking into the source of transistor (M2).

Similar to FIGS. 5A-5E described above, FIG. 6 shows also a set of performance indicator graphs illustrating the performance improvement, e.g., including tunability, when comparing LNA (200A) of FIG. 2A with LNA (100) of FIG. 1. The curves shown include the performance comparison corresponding to different operational frequency bands. Several observations can be made as listed below:
For band-tuning architectures, the output matching network (OMN) is tuned but typically the overall gain for the high-frequency band is lower compared to low-frequency band.
The above is more evident in high frequency circuits because of the dominance of the device parasitic
Degenerative inductance switching combined with OMN can increase gain by improving cascode transconductance, at the expense of S11 deterioration. However, this approach does not address the gain roll-off issue due to the presence of device parasitic
Using a tunable inductor as disclosed, can improve transconductance while resonating out the parasitic. In other words, similar max-min gain can be achieved without significant S11 trade-off
An application in the 5G FR3 frequency band as shown is an example, as band is tuned between wideband 10-12.7 GHZ to narrow/wideband 10-10.5 GHZ (IMT) and 10.7-12.7 GHZ (non-Geostationary satellite)
With only OMN tuning and similar S11 (see solid curves), the gain seems to decrease for higher frequency bands
With tunable CG Feedback Inductor and OMN tuning (see dash-dot curves), the gain is similar for all bands without any significant trade-off

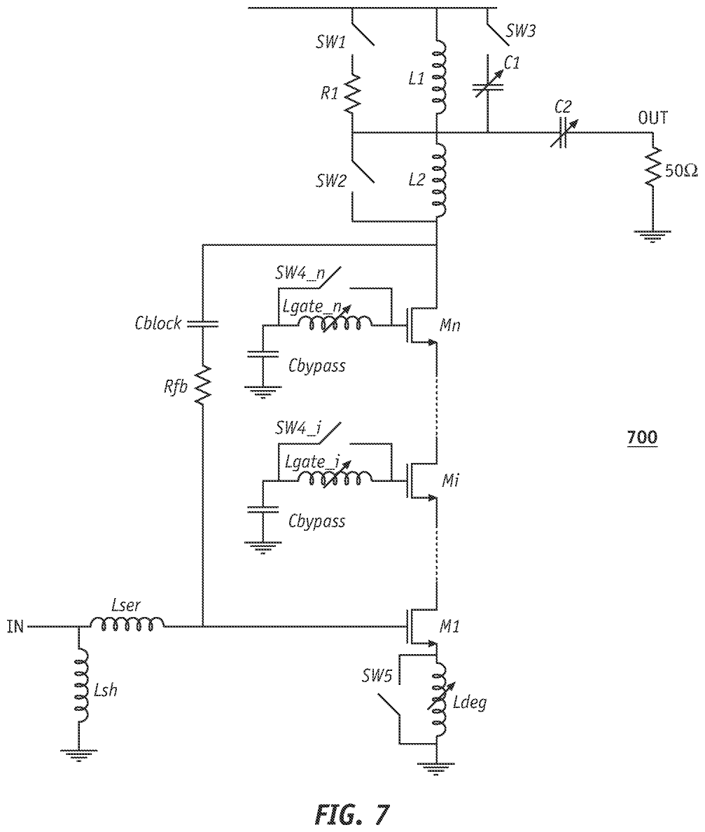

As mentioned previously, the embodiment of FIG. 2A is just one example of LNA architectures benefiting from the present teachings. Other LNA architectures implementing the disclosed concepts may also be envisaged. FIG. 7 shows a further exemplary LNA architecture wherein instead of using two transistors, a stack of transistors (M1, . . . , Mn) arranged in series is implemented. In this LNA the tunable inductor may be implemented in correspondence with one or more of transistors (M2, . . . , Mn). Any of such inductor(s) may or may not be switchable. In the applications where the die space is restricted, the tunable inductor may be preferably only implemented with the top-most transistor, i.e. transistor (Mn) which is the closest to the LNA output.

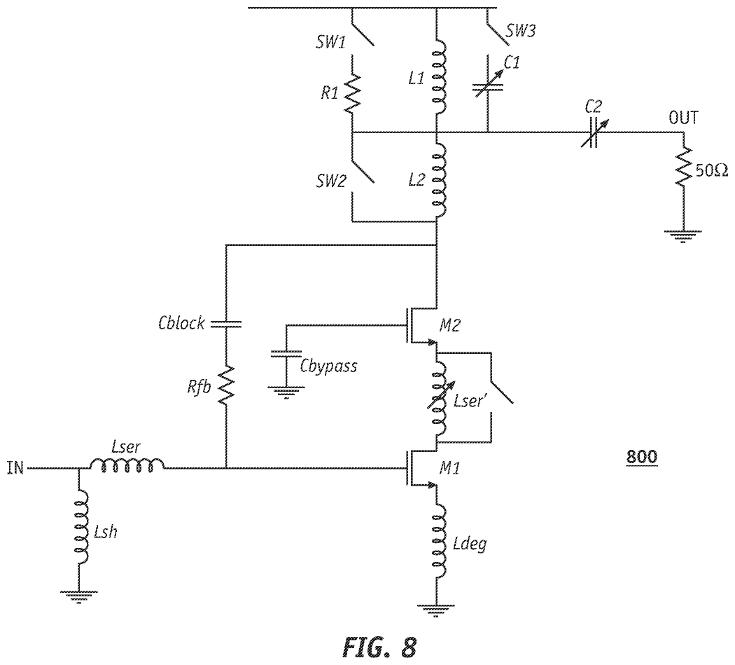

FIG. 8 shows an exemplary LNA (800) in accordance with an embodiment of the present disclosure. This embodiment may be preferably implemented in the applications where noise reduction is the primary goal. As can be seen, a tunable/switchable inductor (Lser') is inserted between the source-terminal of transistor (M2) and the drain terminal of transistor (M1). This addition helps reducing the noise contribution of transistor (M2).

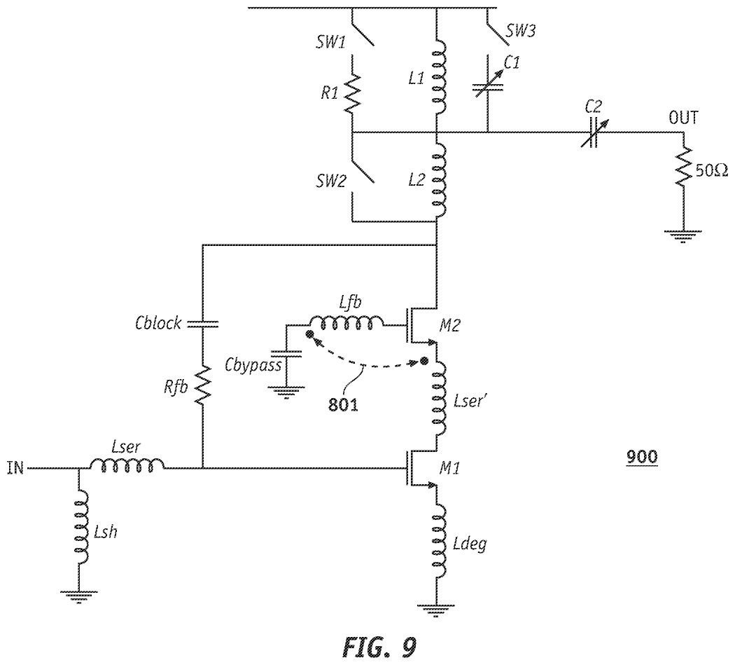

FIG. 9 shows another exemplary LNA (900) in accordance with an embodiment of the present disclosure. In this embodiment, inductors (Lfb, Lser') may or may not be inductively coupled. The coupling is indicated by arrow (801). In an embodiment where, such inductors are coupled, improved performance is achieved in terms of for simultaneous gain boosting and noise reduction, and compared to the case where they are not inductively coupled. In this embodiment, the combination of such inductors functions essentially as a tunable transformer.

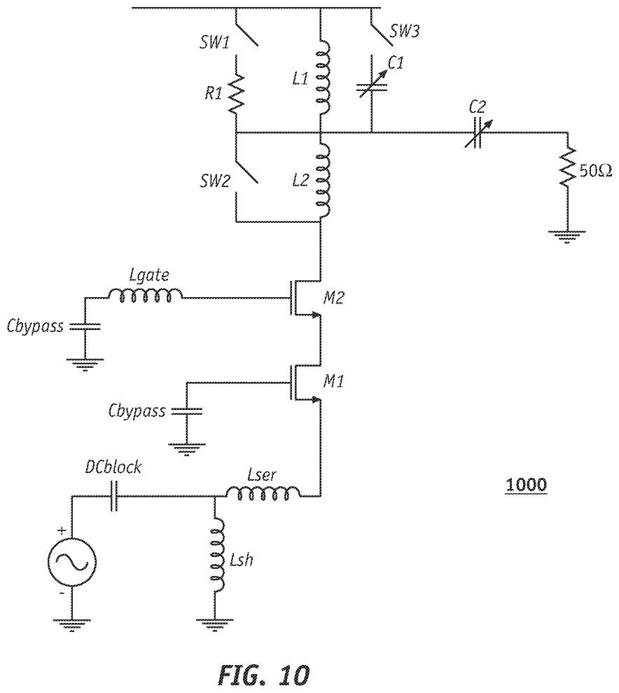

The person skilled in the Art will appreciate that the disclosed teachings can be implemented in any circuital arrangement implementing a transistor arranged in a common-gate configuration. FIG. 10 illustrates this idea where transistors (M1, M2) are implemented in a common-gate configuration. All the principles described previously with regards to the embodiments of FIGS. 2A, 3A-3B are equally applicable here. In other words, by implementing the tunable inductor (Lgate) the gain roll-off issue occurring at higher frequencies associated with transistor (M1), and more in particular its junction capacitance (Cgs) can be overcome.

With respect to the figures referenced in this disclosure, the dimensions for the various elements are not to scale; some dimensions have been greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHZ). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A low noise amplifier (LNA) comprising:
a first transistor and a second transistor arranged in a series configuration, and
a tunable inductor coupling a gate terminal of the second transistor to ground;
wherein:
the LNA is configured to receive an input signal at an input terminal coupled to the first transistor, and to generate an amplified signal at an output terminal coupled to the second transistor; and
the tunable inductor is configured such that a gate-source voltage of the second transistor generated in presence of the tunable inductor is larger than a gate-source voltage of the second transistor generated in absence of the tunable inductor.

2. The LNA of claim 1, wherein the tunable inductor is further configured to resonate out parasitics present at a source terminal of the second transistor.

3. The LNA of claim 1, further comprising an input matching circuit inclusive of a series and a shunt inductor.

4. The LNA of claim 1, further including a degenerative inductor coupling a source terminal of the first transistor to ground.

5. The LNA of claim 4, wherein the degenerative inductor is adjustable and/or selectively switchable.

6. The LNA of claim 1, further including a feedback element coupling a drain terminal of the second transistor to a gate terminal of the first transistor.

7. The LNA of claim 6, wherein the feedback element comprises a series configuration of a feedback inductor and a direct coupling (DC) capacitor.

8. The LNA of claim 7, wherein the feedback inductor is adjustable and/or selectively switchable.

9. The LNA of claim 1, further including an output matching circuit coupled to a drain terminal of the second transistor and to the output terminal.

10. The LNA of claim 1, wherein a resonance frequency of a combination of the tunable inductor and a gate-source capacitance of the second transistor is less than an operating frequency of the LNA.

11. A low noise amplifier (LNA) comprising:
a first transistor and a second transistor, and
a first tunable inductor coupling a drain terminal of the first transistor to a source-terminal of the second transistor;
wherein:
the LNA is configured to receive an input signal at an input terminal coupled to the first transistor, and to generate an amplified signal at an output terminal coupled to the second transistor; and
the first tunable inductor is configured such that a gate-source voltage of the second transistor generated in presence of the first tunable inductor is larger than a gate-source voltage of the second transistor generated in absence of the first tunable inductor.

12. The LNA of claim 11, wherein the first tunable inductor is configured to resonate out parasitics present at the source-terminal of the second transistor.

13. The LNA of claim 11, further comprising a second tunable inductor coupling a gate terminal of the second transistor to ground.

14. The LNA of claim 13, wherein the first tunable inductor and the second tunable inductor are inductively coupled.

15. The LNA of claim 13, wherein the first tunable inductor and the second tunable inductor are selectively switchable.

16. The LNA of claim 13, further comprising a degenerative inductor coupling a source-terminal of the first transistor to ground.

17. The LNA of claim 16, wherein the degenerative inductor is selectively switchable.

18. A low noise amplifier (LNA) comprising:
a first transistor and two or more additional transistors, the first transistor and the two or more additional transistors being arranged in a series configuration, and
one or more tunable inductors coupling gate terminals of corresponding additional transistors of the two or more additional transistors to ground;
wherein:
the LNA is configured to receive an input signal at an input terminal coupled to the first transistor, and to generate an amplified signal at an output terminal coupled to an additional transistor; of the two or more additional transistors; and
the one or more tunable inductors are configured such that gate-source voltages of corresponding additional transistors of the two or more additional transistors generated in presence of the one or more tunable inductors are larger than gate-source voltages of said corresponding additional transistors of the two or more additional transistors generated in absence of the one or more tunable inductors.

19. The LNA of claim 18, wherein at least one tunable inductor of the one or more tunable inductors is selectively switchable.

20.-21. (canceled)
